(19) United States
(12) Patent Application Publication
(10) Pub. No.: US 2015/0195930 A1
(43) Pub. Date: Jul. 9, 2015

(54) VOLUMETRIC BODY FORMED OF TWO CURVED SURFACES AND METHODS FOR PROVIDING THE SAME

(71) Applicant: EZ AS A DRINK PRODUCTIONS, INC., Venice, CA (US)

(72) Inventors: Kostadin Dimitrov Yanev, Alamo, CA (US); Kamen Radev Dobrev, Varna (BG)

(73) Assignee: EZ AS A DRINK PRODUCTIONS, INC., Venice, CA (US)

(21) Appl. No.: 14/149,732

(22) Filed: Jan. 7, 2014

(51) Int. Cl. H05K 5/02

(52) U.S. Cl. CPC H05K 5/0217

(57) ABSTRACT

A volumetric body may be formed of two curved surfaces. The volumetric body may comprise a first surface and a second surface, both being configured to be joined together at a single curved seam to substantially enclose a volume. The first surface may be shaped as an area of a lateral surface of a first cylinder having a first longitudinal axis and a first radius. The second surface may be shaped as an area of a lateral surface of a second cylinder having a second longitudinal axis and a second radius. The seam may be shaped based on an intersection of the first cylinder and the second cylinder when the first longitudinal axis and the second longitudinal axis are noncoplanar, are perpendicular in orthogonal projection, and have a nearest distance that is less than a sum of the first radius and the second radius.

### FIELD OF THE DISCLOSURE

This disclosure relates to various volumetric bodies each formed of two curved surfaces, and methods for providing the same.

### BACKGROUND

Electronics devices may generally be enclosed by an integrated casing to protect internal components. Such a case may provide aesthetic appeal and maintain integrity of a given electronics device during use and storage. The use of planes for such casings may provide advantages in design and production such as the technology and materials used, packaging, storage, bonding, and printing on the external surface. Usually, multiple flat (eventually folded or broken) planes are used that create angles and edges to appear at the borders where planes are connecting to each other.

### SUMMARY

One aspect of the disclosure relates to various volumetric bodies each formed of two curved surfaces. Some implementations may address disadvantages associated with the presence of multiple angles and/or edges introduced by planar surfaces in casings for electronics devices from ergonomic perspective by making them more comfortable when they must be in contact with hands other body parts, especially when some force needs to be applied over the electronics device. Significant compressive or tensive force may be regularly applied to electronics devices designed to facilitate personal exercise through various squeezing and pulling techniques. For example, such a device may be repeatedly squeezed between a user's knees or other body parts to exercise certain muscles. Exemplary implementations may utilize two matching pieces of a curved shape (e.g., a cylinder) to form a closed casing with a single rim thus eliminating the presence of multiple different angles and edges.

A volumetric body may be formed of two curved surfaces and configured as a case of an electronics device. The volumetric body may comprise a first surface and a second surface both configured to be joined together at a single curved seam to substantially enclose a volume. The first surface may be shaped as an area of a lateral surface of a first cylinder having a first longitudinal axis and a first radius. The second surface may be shaped as an area of a lateral surface of a second cylinder having a second longitudinal axis and a second radius. The seam may be shaped based on an intersection of the first cylinder and the second cylinder when the first longitudinal axis and the second longitudinal axis are noncoplanar, are nonparallel in orthogonal projection, and have a nearest distance that is less than a sum of the first radius and the second radius, as described further herein. According to various implementations, the shape of the seam may be further based on the intersection of the first cylinder and the second cylinder when the first longitudinal axis and the second longitudinal axis are perpendicular in orthogonal projection. Such a volumetric body may be provided by a method comprising the steps of: obtaining a first surface and a second surface from one or more cylindrical pipes or tubes; and joining the first surface with the second surface at a single curved seam to substantially enclose a volume.

These and other features, and characteristics of the present technology, as well as the methods of operation and functions of the related elements of structure and the combination of parts and economies of manufacture, will become more apparent upon consideration of the following description and the appended claims with reference to the accompanying drawings, all of which form a part of this specification, wherein like reference numerals designate corresponding parts in the various figures. It is to be expressly understood, however, that the drawings are for the purpose of illustration and description only and are not intended as a definition of the limits of the invention. As used in the specification and in the claims, the singular form of “a”, “an”, and “the” include plural referents unless the context clearly dictates otherwise.

### BRIEF DESCRIPTION OF THE DRAWINGS

FIG. 1 is a perspective view of the bottom side of a volumetric body, in accordance with one or more implementations.

FIG. 2 is a perspective view of the top side of the volumetric body of FIG. 1, in accordance with one or more implementations.

FIG. 3 is an orthogonal view of the front side of the volumetric body of FIG. 1, in accordance with one or more implementations.

FIG. 4 is an orthogonal view of the back side of the volumetric body of FIG. 1, in accordance with one or more implementations.

FIG. 5 is an orthogonal view of the right side of the volumetric body of FIG. 1, in accordance with one or more implementations.

FIG. 6 is an orthogonal view of the left side of the volumetric body of FIG. 1, in accordance with one or more implementations.

FIG. 7 is an orthogonal view of the top side of the volumetric body of FIG. 1, in accordance with one or more implementations.

FIG. 8 is an orthogonal view of the bottom side of the volumetric body of FIG. 1, in accordance with one or more implementations.

FIG. 9 illustrates a first perspective view of various volumetric bodies each formed of two curved surfaces shaped based on intersecting cylinders, in accordance with one or more implementations.

FIG. 10 illustrates a second perspective view of the various volumetric bodies of FIG. 9.

FIG. 11 illustrates an orthogonal projection view of the various volumetric bodies of FIG. 9.

FIG. 12 illustrates an exemplary form and analytical description of a rim of a surface of a volumetric body, in accordance with one or more implementations.

FIG. 13 illustrates a circular cylinder intersecting an oval cylindrical form, in accordance with one or more implementations.

FIG. 14 is an exploded perspective view of a volumetric body with an internal structure, in accordance with one or more implementations.

FIG. 15 illustrates a method for providing a volumetric body formed of two curved surfaces, in accordance with one or more implementations.

### DETAILED DESCRIPTION

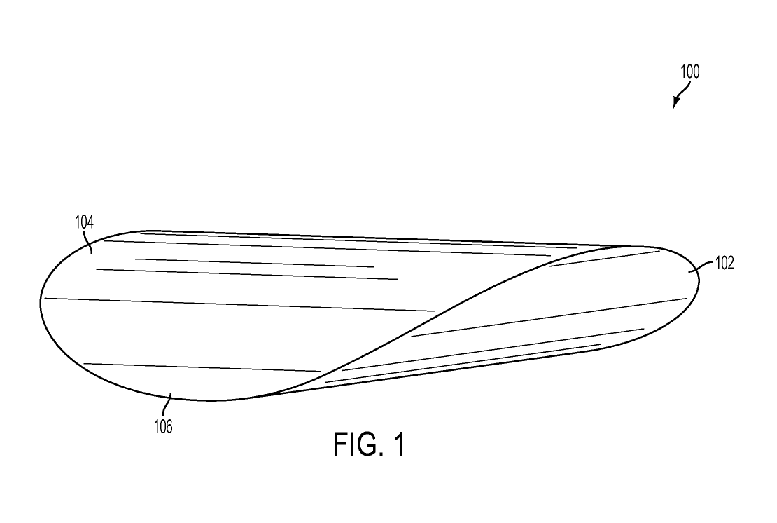

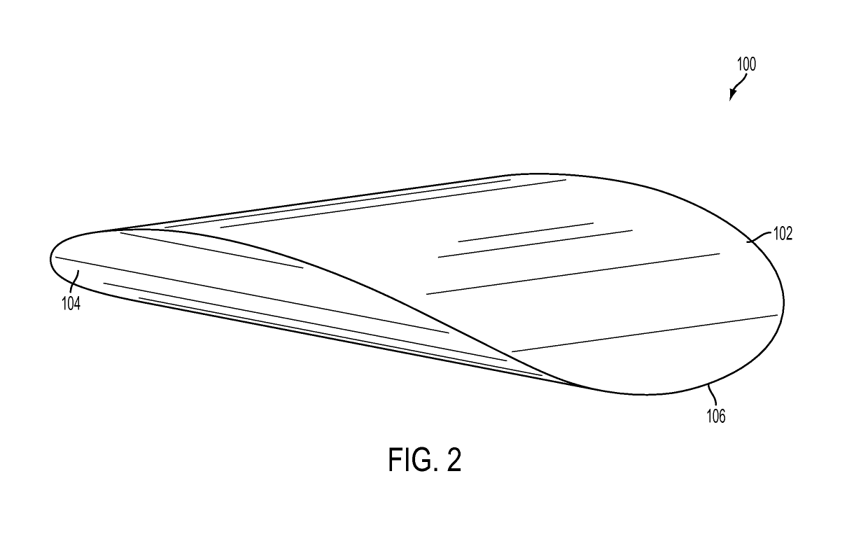

FIG. 1 is a perspective view of the bottom side of a volumetric body 100, and FIG. 2 is a perspective view of the top side of volumetric body 100, in accordance with one or more implementations. The volumetric body 100 may be configured as a case of an electronics device. That is, volumetric body 100 may be configured to contain, support, protect, and/or otherwise integrate with various electronics components (e.g., a display, a user interface, a button, and/or other components), as discussed further herein. While volumetric body 100 is described herein in the context of consumer electronics devices, this is not intended to be limiting as many other applications of volumetric body 100 may exist. For example, volumetric body 100 may be suitable for packaging, storage containers, and/or other applications.

The volumetric body 100 may include a surface 102 and a surface 104. Both surface 102 and surface 104 may be configured to be joined together at a single curved seam 106 to substantially or entirely enclose a volume. The surface 102 may be shaped as an area of a lateral surface of a first cylinder having a first longitudinal axis and a first radius. The surface 106 may be shaped as an area of a lateral surface of a second cylinder having a second longitudinal axis and a second radius. The seam 106 may be shaped based on an intersection of the first cylinder and the second cylinder when the first longitudinal axis and the second longitudinal axis are noncoplanar, are nonparallel in orthogonal projection, and have a nearest distance that is less than a sum of the first radius and the second radius, as described further herein. According to various implementations, the shape of the seam may be further based on the intersection of the first cylinder and the second cylinder when the first longitudinal axis and the second longitudinal axis are perpendicular in orthogonal projection. In some implementations, the nearest distance between the first longitudinal axis and the second longitudinal axis may be greater than a larger one of the first radius and the second radius. The first radius may be equal to the second radius, or the first radius may be larger or smaller than the second radius. The greater of the first radius and the second radius may be less than twice the lesser of the two so that the surfaces that are formed will yield a closed volume.

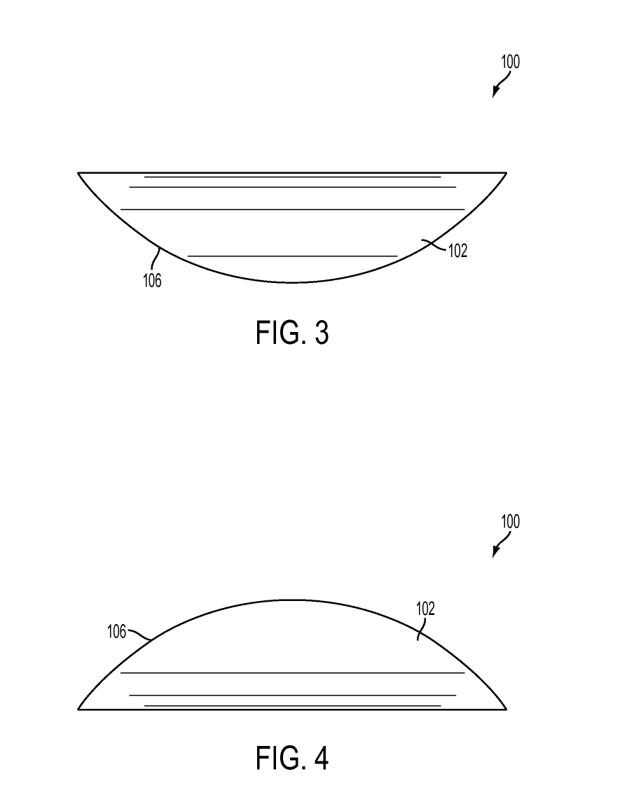

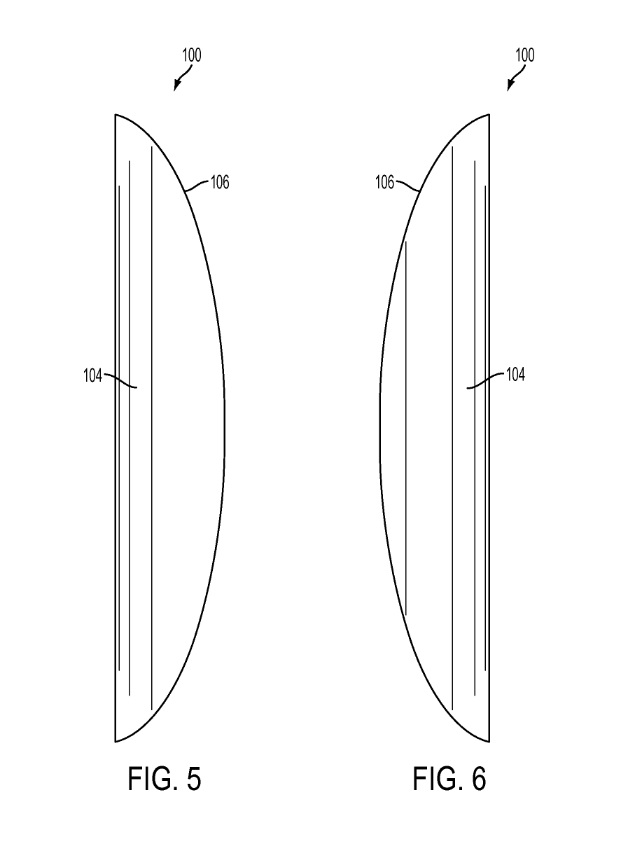

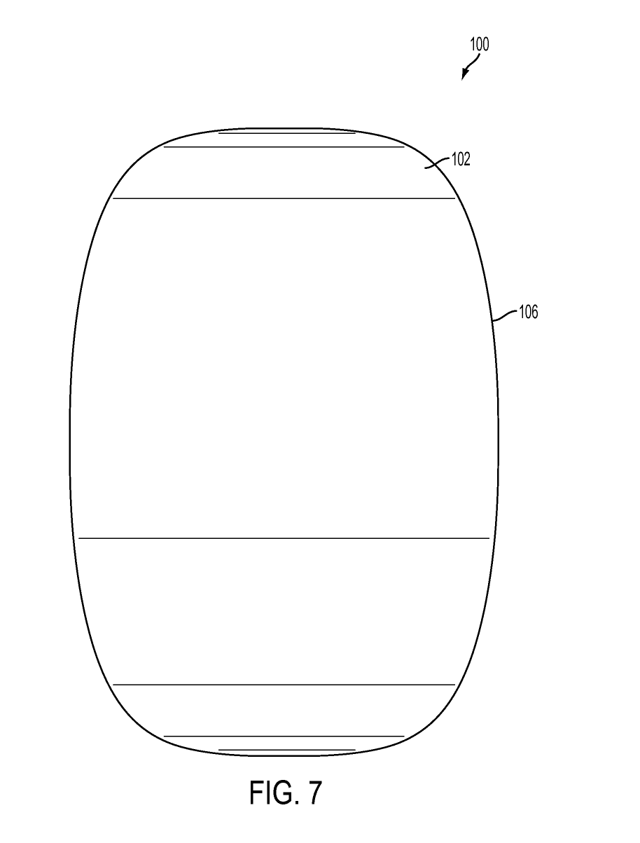

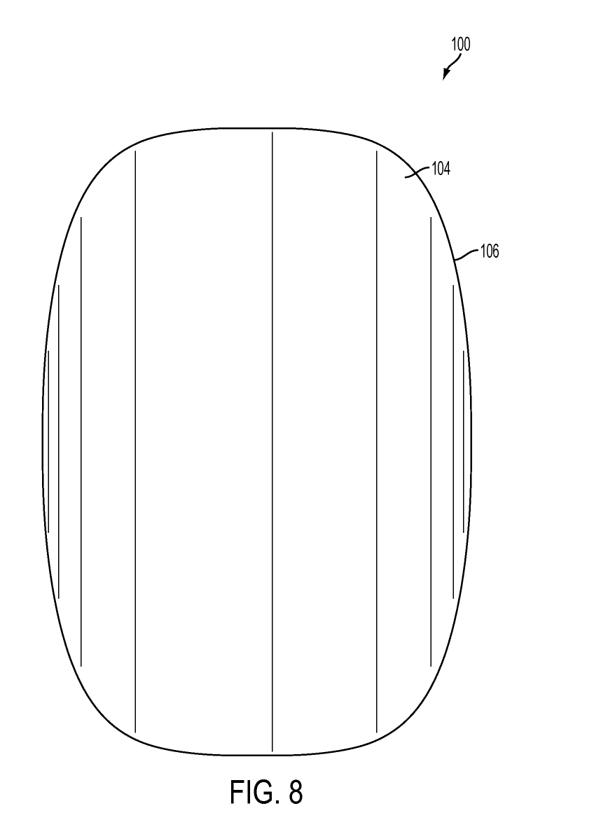

In accordance with some implementations, FIG. 3 is an orthogonal view of the front side of volumetric body 100, FIG. 4 is an orthogonal view of the back side of volumetric body 100, FIG. 5 is an orthogonal view of the right side of volumetric body 100, FIG. 6 is an orthogonal view of the left side of volumetric body 100, FIG. 7 is an orthogonal view of the top side of volumetric body 100, and FIG. 8 is an orthogonal view of the bottom side of volumetric body 100.

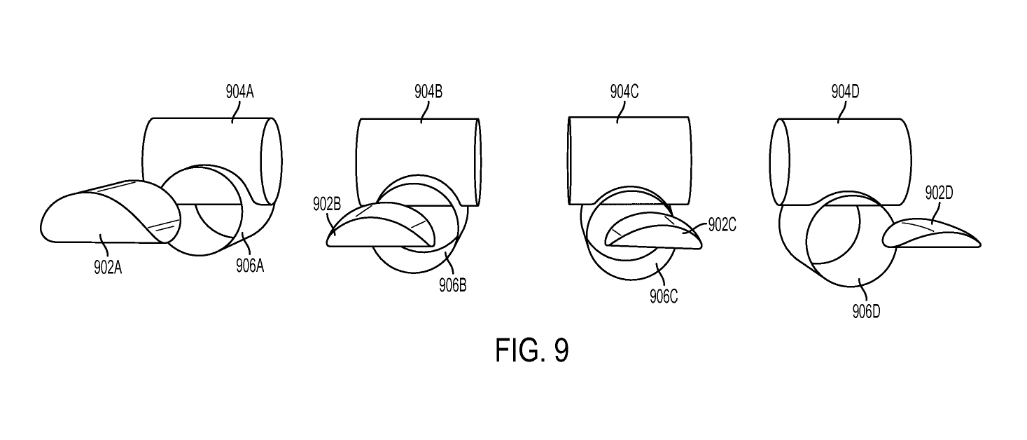

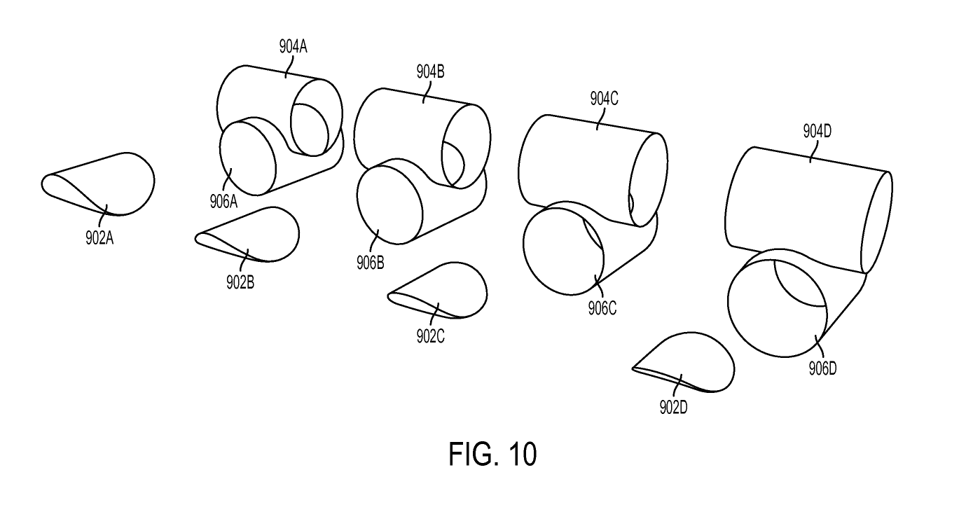

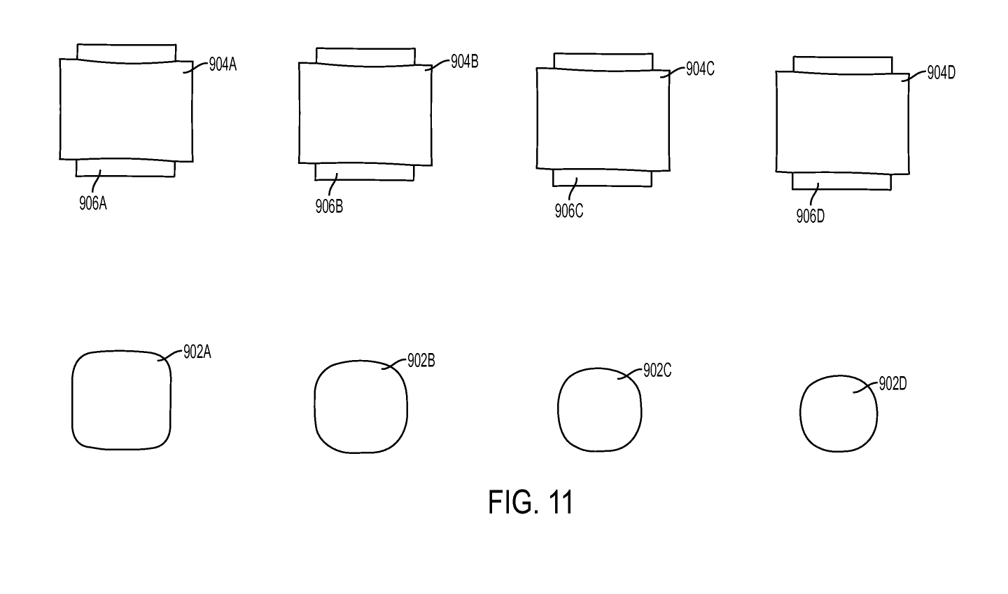

The volumetric body 100 may take on a variety of shapes depending on the amount of overlap of two intersecting cylinders that define the shape of surface 102, surface 104, and seam 106. FIGS. 9 and 10 illustrate different perspective views of a volumetric body 902A, a volumetric body 902B, a volumetric body 902C, and a volumetric body 902D. FIG. 11 illustrates an orthogonal projection view of the various volumetric bodies shown in FIGS. 9 and 10. The shape of volumetric body 902A may be based on the intersection of a cylinder 904A and a cylinder 906A. The shape of volumetric body 902B is based on the intersection of a cylinder 904B and a cylinder 906B. The shape of volumetric body 902A is based on the intersection of a cylinder 904C and a cylinder 906C. The shape of volumetric body 902D is based on the intersection of a cylinder 904D and a cylinder 906D. The radii of cylinders 904A, 904B, 904C, and 904D may be the same, and the radii of cylinders 906A, 906B, 906C, and 906D may be the same.

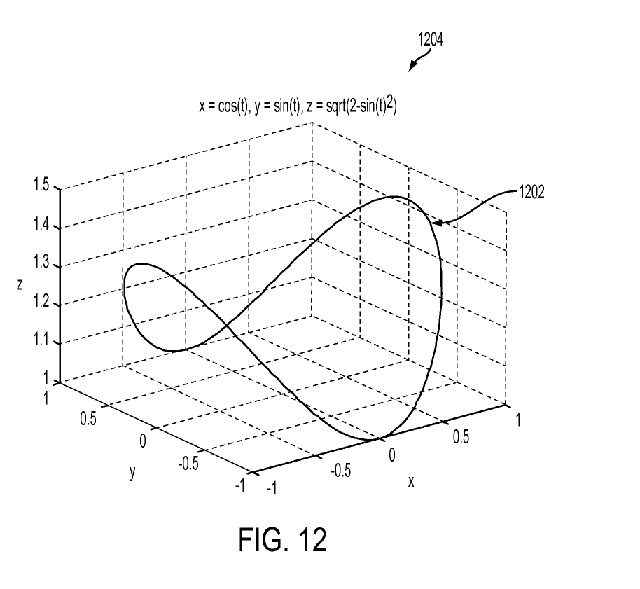

The shapes of volumetric body 902A, volumetric body 902B, volumetric body 902C, and volumetric body 902D differ because the cylinders that are the basis for the respective shapes intersect and overlap by varying degrees. More specifically, a closest distance between a longitudinal axis of cylinder 904A and a longitudinal axis of cylinder 906A is smaller than a closest distance between a longitudinal axis of cylinder 904D and a longitudinal axis of cylinder 906D. The resulting volumes, therefore, vary in thickness and shape. FIG. 12 illustrates an exemplary form 1202 and analytical description 1204 of a rim of a surface of a volumetric body formed by surfaces of similar radii of curvature, in accordance with one or more implementations.

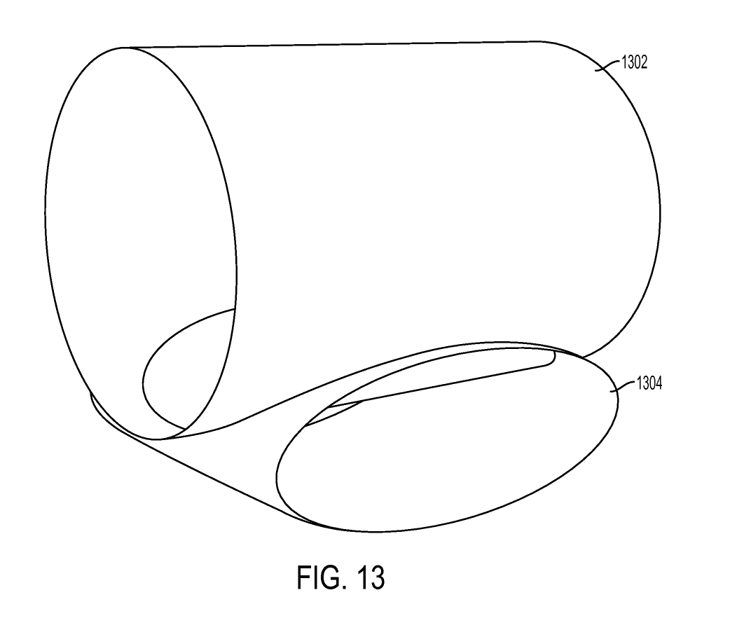

In some implementations, surface 102 and/or surface 104 may be obtained from or by using a cylindrical pipe or tube. For example, a cylindrical pipe or tube may be a source material for surface 102 and/or surface 104. This may reduce fabrication costs of volumetric body 100 because surface 102 and/or surface 104 may be cut directly from stock cylindrical materials, instead of being molded or formed by three-dimensional printing. According to some implementations, a cylinder may be used as a form for surface 102 and/or surface 104. By way of non-limiting example, surface 102 and/or surface 104 may be formed of plastic, metal, rubber, and/or other materials. While surface 102 and surface 104 are described herein as being shaped based on areas of lateral surfaces of cylinders, this is not intended to be limiting as other shapes may form a basis for the shape of surface 102 and/or surface 104, in some implementations. For example, surface 102 and/or surface 104 may be shaped based on an area of a lateral surface of a truncated cone, cylindrical forms with textured or corrugated surfaces, oval or elliptical cylinder forms, and/or other shapes. FIG. 13 illustrates a circular cylinder 1302 intersecting an oval cylindrical form 1304, in accordance with one or more implementations.

As mentioned above, surface 102 and surface 104 may be joined at seam 106. A physical connection between surface 102 and surface 104 may be permanent or temporary. For example, a permanent connection between surface 102 and surface 104 may be established by fusing, welding, gluing, press-fitting, bonding, and/or other techniques for providing permanent connections between parts. A temporary connection between surface 102 and surface 104 may be provided by snaps, pins, hinges, press-fitting, screws, hook and loop fastener (e.g., Velcro®), static attraction, and/or other techniques for providing temporary connection between parts.

According to some implementations, surface 102 may be configured to linearly translate along a longitudinal axis of surface 102 in order to open volumetric body 100, wherein the linear translation is relative to surface 104. In some implementations, both surface 102 and surface 104 may be configured to translate along their respective longitudinal axes relative to the other surface.

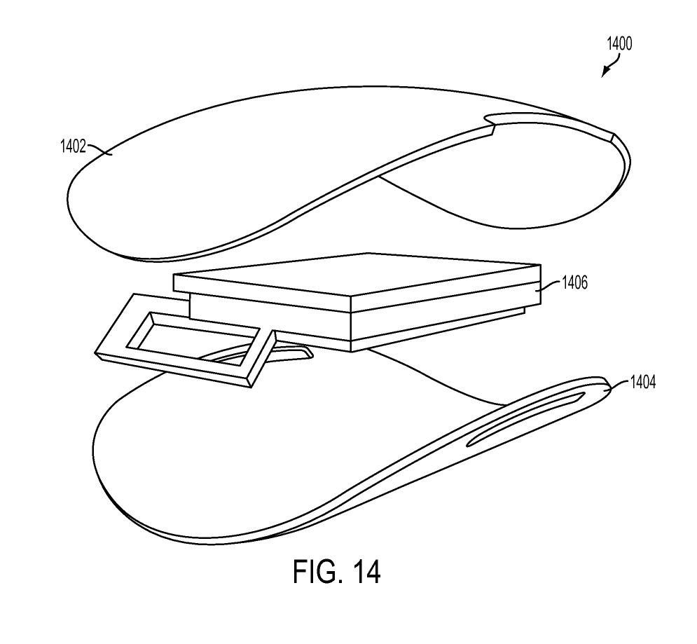

The volumetric body 100 may include an internal structure. FIG. 14 is an exploded perspective view of a volumetric body 1400 that includes a first surface 1402, a second surface 1404, and an internal structure 1406, in accordance with one or more implementations. The internal structure 1406 may be configured to support one or more components with in volumetric body 1400. The internal structure 1406 may include a bracket, frame, and/or other structure. The internal structure 1406 may be integrated with one or both of surfaces 1404 or 1406. Surfaces 1404 and 1406, when joined together, may hold internal structure 1406 in place. Examples of components supported by internal structure 1406 may include electronics components and/or components. Examples of electronic components may include one or more of a power source (e.g., battery or capacitor), a display, a button, a switch, a user interface, a communications interface (wired or wireless), a processor, and/or other electronics components.

In some implementations, an electronics device utilizing volumetric body 100 may be operatively linked to one or more other electronics devices or computing platforms (e.g., a desktop computer, a laptop computer, a handheld computer, a tablet computing platform, a NetBook, a Smartphone, a gaming console, and/or other computing platforms) via one or more electronic communication links. For example, such electronic communication links may be established, at least in part, via a network such as the Internet and/or other networks. It will be appreciated that this is not intended to be limiting, and that the scope of this disclosure includes implementations in which an electronics device utilizing volumetric body 100 may be operatively linked via some other communication media.

An electronics device utilizing volumetric body 100 may include electronic storage (not depicted), one or more processors (not depicted), and/or other components. An electronics device utilizing volumetric body 100 may include communication lines, or ports to enable the exchange of information with a network and/or other computing platforms.

Electronic storage may comprise non-transitory storage media that electronically stores information. The electronic storage media of electronic storage may include one or both of system storage that is provided integrally (i.e., substantially non-removable) with an electronics device utilizing volumetric body 100 and/or removable storage that is removably connectable to an electronics device utilizing volumetric body 100 via, for example, a port (e.g., a USB port, a firewire port, etc.) or a drive (e.g., a disk drive, etc.). Electronic storage may include one or more of optically readable storage media (e.g., optical disks, etc.), magnetically readable storage media (e.g., magnetic tape, magnetic hard drive, floppy drive, etc.), electrical charge-based storage media (e.g., EEPROM, RAM, etc.), solid-state storage media (e.g., flash drive, etc.), and/or other electronically readable storage media. Electronic storage may include one or more virtual storage resources (e.g., cloud storage, a virtual private network, and/or other virtual storage resources). Electronic storage may store software algorithms, information determined by a processor, information received from other electronics devices and/or computing platforms, and/or other information.

A processor included in an electronics device utilizing volumetric body 100 may be configured to provide information processing capabilities in the electronics device utilizing volumetric body 100. As such, the processor may include one or more of a digital processor, an analog processor, a digital circuit designed to process information, an analog circuit designed to process information, a state machine, and/or other mechanisms for electronically processing information. The processor may be configured to execute computer program instructions, modules, and/or components. The processor may be configured to execute computer program instructions, modules, and/or components by software; hardware; firmware; some combination of software, hardware, and/or firmware; and/or other mechanisms for configuring processing capabilities on a processor. As used herein, the term “module” may refer to any component or set of components that perform the functionality attributed to the module. This may include one or more physical processors during execution of processor readable instructions, the processor readable instructions, circuitry, hardware, storage media, or any other components.

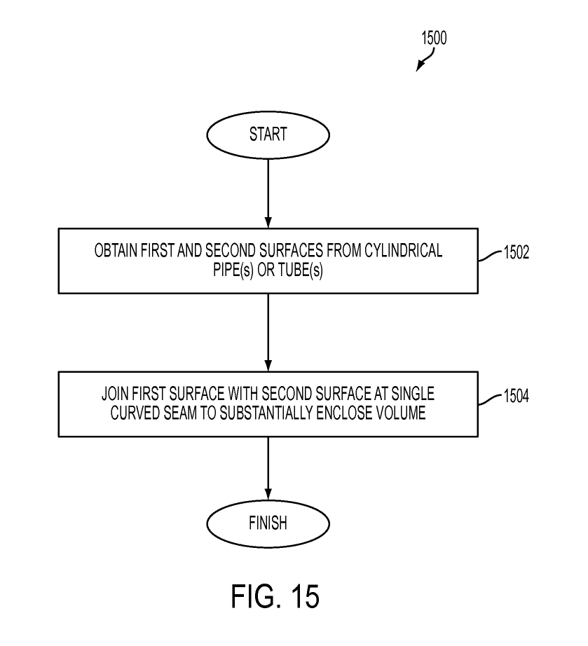

FIG. 15 illustrates a method 1500 for providing a volumetric body formed of two curved surfaces, in accordance with one or more implementations. The operations of method 1500 presented below are intended to be illustrative. In some implementations, method 1500 may be accomplished with one or more additional operations not described, and/or without one or more of the operations discussed. Additionally, the order in which the operations of method 1500 are illustrated in FIG. 15 and described below is not intended to be limiting.

At an operation 1502, a first surface and a second surface may be obtained from from one or more cylindrical pipes or tubes. In some implementations, the first surface and/or the second surface are cut from the one or more cylindrical pipes or tubes. The first surface may be shaped as an area of a lateral surface of a first cylinder having a first longitudinal axis and a first radius. The second surface may be shaped as an area of a lateral surface of a second cylinder having a second longitudinal axis and a second radius. In some implementations, the first cylinder and the second cylinder may be the same, or the first cylinder and the second cylinder may be different sizes and/or materials.

At an operation 1504, the first surface may be joined with the second surface at a single curved seam to substantially enclose a volume. The seam may be shaped based on an intersection of the first cylinder and the second cylinder when the first longitudinal axis and the second longitudinal axis are noncoplanar, are nonparallel (e.g., perpendicular) in orthogonal projection, and have a nearest distance that is less than a sum of the first radius and the second radius.

Although the present technology has been described in detail for the purpose of illustration based on what is currently considered to be the most practical and preferred implementations, it is to be understood that such detail is solely for that purpose and that the technology is not limited to the disclosed implementations, but, on the contrary, is intended to cover modifications and equivalent arrangements that are within the spirit and scope of the appended claims. For example, it is to be understood that the present technology contemplates that, to the extent possible, one or more features of any implementation can be combined with one or more features of any other implementation.

1. A method for providing a volumetric body formed of two curved surfaces and configured as a case of an electronics device, the method comprising:
obtaining a first surface and a second surface from one or more cylindrical pipes or tubes; and
joining the first surface with the second surface at a single curved seam to substantially enclose a volume;
wherein:
the first surface is shaped as an area of a lateral surface of a first cylinder having a first longitudinal axis and a first radius;
the second surface is shaped as an area of a lateral surface of a second cylinder having a second longitudinal axis and a second radius; and
the seam is shaped based on an intersection of the first cylinder and the second cylinder when the first longitudinal axis and the second longitudinal axis are noncoplanar, are perpendicular in orthogonal projection, and have a nearest distance that is less than a sum of the first radius and the second radius.

2. The method of claim 1, wherein the nearest distance between the first longitudinal axis and the second longitudinal axis is greater than a larger one of the first radius and the second radius.

3. The method of claim 1, wherein the first radius is equal to the second radius.

4. The method of claim 1, wherein the first radius is larger than the second radius.

5. The method of claim 1, wherein the volumetric body consists of the first surface and the second surface.

6. The method of claim 1, wherein the first surface is configured to linearly translate along a longitudinal axis of the first surface in order to open the volumetric body, the linear translation being relative to the second surface.

7. The method of claim 1, wherein the first surface is configured to linearly translate along a longitudinal axis of the first surface in order to open the volumetric body, and the second surface is configured to linearly translate alone a longitudinal axis of the second surface in order to open the volumetric body, the linear translation of the first surface being relative to the second surface, and the linear translation of the second surface being relative to the first surface.

8. The method of claim 1, further comprising an internal structure configured to support one or more electronics components.

9. A volumetric body formed of two curved surfaces and configured as a case of an electronics device, the volumetric body comprising:
a first surface and a second surface both configured to be joined together at a single curved seam to substantially enclose a volume;
the first surface being shaped as an area of a lateral surface of a first cylinder having a first longitudinal axis and a first radius;
the second surface being shaped as an area of a lateral surface of a second cylinder having a second longitudinal axis and a second radius; and
the seam being shaped based on an intersection of the first cylinder and the second cylinder when the first longitudinal axis and the second longitudinal axis are noncoplanar, are perpendicular in orthogonal projection, and have a nearest distance that is less than a sum of the first radius and the second radius.

10. The volumetric body of claim 9, wherein the nearest distance between the first longitudinal axis and the second longitudinal axis is greater than a larger one of the first radius and the second radius.

11. The volumetric body of claim 9, wherein the first radius is equal to the second radius.

12. The volumetric body of claim 9, wherein the first radius is larger than the second radius.

13. The volumetric body of claim 9, wherein the first surface is obtained from a cylindrical pipe or tube.

14. The volumetric body of claim 9, wherein a cylindrical pipe or tube is a source material for the first surface.

15. The volumetric body of claim 9, wherein the volumetric body consists of the first surface and the second surface.

16. The volumetric body of claim 9, wherein the first surface is configured to linearly translate along a longitudinal axis of the first surface in order to open the volumetric body, the linear translation being relative to the second surface.

17. The volumetric body of claim 9, wherein the first surface is configured to linearly translate along a longitudinal axis of the first surface in order to open the volumetric body, and the second surface is configured to linearly translate alone a longitudinal axis of the second surface in order to open the volumetric body, the linear translation of the first surface being relative to the second surface, and the linear translation of the second surface being relative to the first surface.

18. The volumetric body of claim 9, further comprising an internal structure configured to support one or more electronics components.
